(19) United States
(12) Patent Application Publication
(10) Pub. No.: US 2024/0059088 A1
(43) Pub. Date: Feb. 22, 2024

(54) SILICA ENCAPSULATED PIGMENTS FOR NANO-METALLOGRAPHY

(71) Applicant: ECKART GmbH, Hartenstein (DE)

(72) Inventors: Oliver BEDFORD, Eckental (DE); Dieter PRÖLSS, Hartenstein (DE); Oliver STRUCK, Hartenstein (DE); Maximilian BOEHMER, Munster (DE)

(21) Appl. No.: 18/269,659

(22) PCT Filed: Dec. 22, 2021
(86) PCT No.: PCT/EP2021/087314

§ 371 Date: Jun. 26, 2023

(30) Foreign Application Priority Data
Jan. 11, 2021 (EP) 21150836.1

(51) Int. Cl. B41M 1/22; C09C 3/00; C23C 14/14; C09C 1/64; B41M 3/00

(52) U.S. Cl. CPC B41M 1/22; C09C 3/006; C23C 14/14; C09C 1/64; B41M 3/006

(57) ABSTRACT

The invention relates to a method of printing onto the surface of a substrate, which method comprises a. coating a donor surface with individual particles, b. treating the surface of the substrate to render the affinity of the particles to at least selected regions of the surface of the substrate greater than the affinity of the particles to the donor surface, and c. contacting the surface of the substrate with the donor surface to cause particles to transfer from the donor surface only to the treated selected regions of the surface of the substrate, thereby exposing regions of the donor surface from which particles are transferred to the corresponding regions on the substrate, and wherein that at least 50 wt. % of the particles are metal pigments comprising a metallic substrate and a surface treatment of the metallic substrate, wherein the surface treatment of the metallic substrate comprises at least one coating layer surrounding the metallic substrate comprising a metal oxide, and a surface modification of the metal oxide layer comprising at least one heteropolysiloxane or a compound having at least two terminal functional groups which are the same or different from each other and which are spaced by a spacer, wherein at least one terminal functional group is capable of being chemically bound to the metal oxide layer.

The present invention relates to a method for printing on a substrate and more in particular to a method capable of applying a layer having a metallic appearance to a substrate.

Various systems are known in the art to print a layer having a metallic appearance of a substrate such as paper or plastic film. These systems fall into two broad categories, viz. foil stamping or foil fusing. One of the main disadvantages of both methods is the large amount of foil that is wasted in these processes, since foil area that is not transferred to form the desired image on a substrate cannot be recovered for use in the same process. Since metal foils are expensive, these processes are relatively costly, as the foil can only be used once and only a small part of the metal is effectively transferred to the substrate.

In WO 2016/189515 A9 a new process is disclosed which enables the printing of a layer having a metallic appearance to a substrate in a much more cost-effective way without any waste of metal or metallized foil. In this process individual metal particles are transferred onto a substrate through a donor roll, wherein the metal particles on the donor roll are replenished in a repeating process. Although this process does not have all the disadvantages of the foil stamping or foil fusing process, it was found that the gloss of the metallic layer obtained through this process was not very high and/or showed degradation over time.

Surprisingly, a process was found that does not show the various disadvantages of the above-described processes, in particular the process according to the present invention provides for the printing of a layer having a metallic appearance onto a substrate, where this layer has a high gloss level which does not show any degradation over time.

The process according to the present invention relates to a method of printing onto a surface of a substrate, which method comprises
a. Providing a donor surface
b. Passing the donor surface through a coating station from which the donor surface exits coated with individual particles, and
c. Repeatedly performing the steps of
   i. Treating the surface of the substrate to render the affinity of the particles to at least selected regions of the surface of the substrate greater than the affinity of the particles to the donor surface,
   ii. Contacting the surface of the substrate with the donor surface to cause particles to transfer from the donor surface only to the treated selected regions of the surface of the substrate, thereby exposing regions of the donor surface from which particles are transferred to the corresponding regions on the substrate, and
   iii. Thereby generating a plurality of individual particles adhered to the treated surface of the substrate
   iv. Returning the donor surface to the coating station to render the particle monolayer continuous in order to permit printing of a subsequent image on the surface of the substrate,
wherein at least 50 wt. % of the particles are metal pigments comprising a metallic substrate and a surface treatment of the metallic substrate, wherein the surface treatment of the metallic substrate comprises at least one coating layer surrounding the metallic substrate comprising a metal oxide and a surface modification of the coating layer comprising at least one heteropolysiloxane or a compound having at least two terminal functional groups which are the same or different from each other and which are spaced by a spacer, wherein at least one terminal functional group is capable of being chemically bound to the coating layer.

This method may further include a cleaning step, during which particles remaining on the donor surface after contacting the substrate are removed from the donor surface, so that prior to the next passage through the cleaning station the donor surface is substantially devoid of particles. Such cleaning step may be performed during each printing cycle or periodically, for instance in between print jobs, changes of particles and the like. A printing cycle corresponds to the time period in-between subsequent passing of a reference point on the donor surface through the coating station, such passage resulting from the donor surface being movable with respect to the coating station.

The donor surface coated with particles is used in a manner analogous to the foil used in foil imaging. However, unlike foil imaging, the damage caused to the continuity of the particle layer on the donor surface by each impression can be repaired by re-coating only the exposed regions of the donor surface from which the previously applied layer has been stripped by transfer to the selected regions of the substrate.

The reason that the particle layer on the donor surface can be repaired after each impression is that the particles are selected to adhere to the donor surface more strongly than they do to one another. This results in the applied layer being substantially a monolayer of individual particles.

Preferably, in step b the donor surface exits the coating station coated with a monolayer of particles. The term “monolayer” is used herein to describe a layer of particles on the donor surface in which at least 60% of the particles is in direct contact with the donor surface, in some embodiments from 70-100% of the particles is in direct contact with the donor surface, in a further embodiment from 85-100% of the particles is in direct contact with the donor surface. While some overlap may occur between particles contacting any such surface, the layer may be only one particle deep over a major proportion of the area of the surface. The monolayer herein is formed from the particles in sufficient contact with the donor surface and is therefore typically a single particle thick. Direct contact means that for the particle to remain attached to the donor surface at the exit of the coating station, e.g., following surplus extraction, burnishing, or any other like step.

To obtain a mirror-like of high gloss area on (selected parts of) the substrate, the selected surface should be sufficiently covered with the particles, which means that at least 70% of the selected surface is covered with the particles, or at least 80%, or at least 90% or at least 95% of the selected surface is covered with particles. The percentage of an area covered by particles out of a specific target surface can be assessed by numerous methods known to skilled persons, including by determination of optical density possibly in combination with the establishment of a calibration curve of known coverage points, by measurement of transmitted light if the substrate is sufficiently transparent or by measurement of reflected light as the particles are reflective.

A preferred method of determining the percentage area of a surface of interest covered by particles is as follows. Squared samples having 1 cm edges are cut from the surface being studied (e.g. from the donor surface or from the printed substrate). The samples are analyzed by microscopy (either laser confocal microscopy (Olympus®, LEXT OLS30ISU) or optical microscopy (Olympus® BX61 U-LH100-3)) at a magnification of up to ×100 (yielding a field of view of at least about 128.9 μm×128.6 μm). At least three representative images are captured in reflectance mode. The captured images were analyzed using ImageJ, a public domain Java image processing program developed by the National Institute of Health (NIH), USA. The images are displayed in 8-bit, gray scale, the program being instructed to propose a threshold value of reflectance differentiating between the reflective particles (lighter pixels) and the interstices that may exist between neighboring or adjacent particles (such voids appearing as darker pixels). A trained operator may adjust the proposed threshold value, if needed, but typically confirms it. The image analysis program then proceed to measure the amount of pixels representing the particles and the amount of pixels representing the uncovered areas of the intra-particle voids, from which the percent area of coverage can be readily calculated. Measurements done on the different image sections of the same sample are averaged. When the samples are printed on a transparent substrate (e.g. a translucent plastic foil), a similar analysis can be done in transmittance mode, the particles appearing as darker pixels and the voids as lighter ones. Results obtained by such methods, or by any substantially similar analytical techniques known to those of skill in the art, are referred to as optical surface coverage, which can be expressed in percent or as a ratio.

If printing is to take place on the entire surface of the substrate, the receptive layer, which may for example be an adhesive, may be applied to the substrate during step I by a roller before it is pressed against the donor surface.

Most preferably a receptive and/or adhesive layer is applied onto the substrate in step i.

Especially if printing is only to take place on selected regions of the substrate, on the other hand, then it is possible to apply the adhesive layer or receptive layer by any conventional printing method, for example by means of a die or printing plates, or by jetting the receptive layer onto the surface of the substrate. In other embodiments the receptive layer is applied to the substrate surface by an indirect printing method such as offset printing, screen printing, flexographic printing or gravure printing.

As a further option, it is possible to coat the entire surface of the substrate with an activatable receptive layer that is selectively rendered “tacky” by suitable activation means. Whether selectively applied or selectively activated, the receptive layer in such case forms a pattern constituting at least part of the image being printed on the substrate.

The term “tacky” is used herein only to indicate that the substrate surface, or any selected region thereof, has sufficient affinity to the particles to separate them from the donor surface and/or to retain them on the substrate, when the two are pressed one against the other at an impression station, and it need not necessarily be tacky to the touch. To permit the printing of patterns in selected regions of the substrate, the affinity of the receptive layer, activated if needed, towards the particles needs to be greater than the affinity of the bare substrate to the particles. In the present context, a substrate is termed “bare” if lacking a receptive layer or lacking a suitably activated receptive layer, as the case may be. Though the bare substrate should for most purposes have substantially no affinity to the particles, to enable the selective affinity of the receptive layer, some residual affinity can be tolerated (e.g., if not visually detectable) or even desired for particular printing effects.

The receptive layer may, for instance, be activated by exposure to radiation (e.g., UV, IR and near IR) prior to being pressed against the donor surface. Other means of receptive layer activation include temperature, pressure, moisture (e.g., for rewettable adhesives) and even ultrasound, and such means of treating the receptive layer surface of a substrate can be combined to render tacky the compatible receptive layer.

Though the nature of the receptive layer being applied to the surface of the substrate may differ, among other things, from substrate to substrate, with the mode of application and/or the selected means of activation, such formulations are known in the art and need not be further detailed for an understanding of the present printing method and system. Briefly, thermoplastic, thermosetting or hot-melt polymers compatible with the intended substrate and displaying sufficient tackiness, relative affinity, to the envisioned particle, optionally upon activation, can be used for the implementation of the present disclosure. Preferably the receptive layer is selected so that it does not interfere with the desired printing effect (e.g., clear, transparent, and/or colourless).

A desired feature of the suitable adhesives relates to the relatively short time period required for activating the receptive layer, i.e., selectively changing the receptive layer from a non-tacky state to a tacky state, increasing the affinity of the selected region of the substrate so that it becomes sufficiently attached to the particles to separate them from the donor surface. Fast activation times enable the receptive layer to be used in high-speed printing. Adhesives suitable for implementation of the present disclosure are preferably capable of activation within a period of time no longer than the time it takes the substrate to travel from an activating station to the impression station.

In some embodiments, activation of the receptive layer can take place substantially instantaneously at the time of the impression. In other embodiments, the activation station or step may precede the impression, in which case the receptive layer can be activated within a time period of less than 10 seconds or 1 second, in particular in a time period of less than about 0.1 second and even less than 0.01 second. This time period is referred to herein as the receptive layer's “activation time.”

As already mentioned, a suitable receptive layer needs to have sufficient affinity with the particles to form the monolayer according to the present teachings. This affinity, which can be alternatively considered as an intimate contact between the two, needs to be sufficient to retain the particles on the surface of the receptive layer and can result from the respective physical and/or chemical properties of the layer and the particles. For instance, the receptive layer may have a hardness sufficiently high to provide for satisfactory print quality, but sufficiently low to permit the adhesion of the particles to the layer. Such optimum range can be seen as enabling the receptive layer to be “locally deformable” at the scale of the particles, so as to form sufficient contact. Such affinity or contact can be additionally increased by chemical bonding. For instance, the materials forming the receptive layer can be selected to have functional groups suitable to retain the particles by reversible bonding (supporting non-covalent electrostatic interactions, hydrogen bonds and

Van der Waals interactions) or by covalent bonding. Likewise, the receptive layer needs be suitable to the intended printing substrate, all above considerations being known to the skilled person.

The receptive layer can have a wide range of thicknesses, depending for example on the printing substrate and/or on the desired printing effect. A relatively thick receptive layer can provide for an “embossing” aspect, the design being raised above the surface of the surrounding substrate. A relatively thin receptive layer can follow the contour of the surface of the printing substrate, and for instance for rough substrates enable a matte aspect. For glossy aspect, the thickness of the receptive layer is typically selected to mask the substrate roughness, so as to provide an even surface. For instance, for very smooth substrates, such as plastic films, the receptive layer may have a thickness of only a few tens of nanometres, for example of about 100 nm for a polyester film (for instance a polyethylene terephthalate (PET) foil) having a surface roughness of 50 nm, smoother PET films allowing to use even thinner receptive layers. Substrates having rougher surfaces in the micron, or tens of microns, range will benefit of a receptive layer having a thickness in the same size range or order of size range, if glossy effect, hence some levelling/masking of substrate roughness is desired. Therefore, depending on the substrate and/or desired effect, the receptive layer can have a thickness of at least 10 nm, or at least 50 nm, or at least 100 nm, or at least 500 nm, or at least 1,000 nm. For effects that can be perceptible by tactile and/or visual detection, the receptive layer may even have a thickness of at least 1.2 micrometres (μm), at least 1.5 μm, at least 2 μm, at least 3 μm, at least 5 μm, at least 10 μm, at least 20 μm, at least 30 μm, at least 50 μm, or at least 100 μm. Though some effects and/or substrates (e.g., cardboard, carton, fabric, leather and the like) may require receptive layers having a thickness in the millimetre range, the thickness of the receptive layer typically does not exceed 800 micrometres (μm), being at most 600 μm, at most 500 μm, at most 300 μm, at most 250 μm, at most 200 μm, or at most 150 μm.

After printing has taken place, namely after the particles are transferred from the donor surface to the tacky regions of the treated substrate surface (i.e. the receptive layer) upon pressing, the substrate may be further processed, such as by application of heat and/or pressure, to fix or burnish the printed image and/or it may be coated with a varnish (e.g. colourless or coloured transparent, translucent, or opaque overcoat) to protect the printed surface and/or it may be overprinted with an ink of a different colour (e.g. forming a foreground image). While some post-transfer steps may be performed on the entire surface of the printed substrate (e.g. further pressure), other steps may be applied only to selected parts thereof. For instance, a varnish may be selectively applied to parts of the image, for instance to the selected regions coated with the particles, optionally further imparting a colouring effect.

Any device suitable to perform any such post-transfer step can be referred to as a post-transfer device (e.g., a coating device, a burnishing device, a pressing device, a heating device, a curing device, and the like). Post-transfer devices may additionally include any finishing device conventionally used in printing systems (e.g., a laminating device, a cutting device, a trimming device, a punching device, an embossing device, a perforating device, a creasing device, a binding device, a folding device, and the like). Post-transfer devices can be any suitable conventional equipment, and their integration in the present printing system will be clear to the person skilled in the art without the need for more detailed description.

In the process according to the present invention the particles comprising at least 50% of flaky metallic substrate, but preferably 75% of the particles comprise a flaky metallic substrate, more preferably at least 85% and most preferably 95 to 100% of the particles comprise a flaky metallic substrate.

In one of the embodiments of the process according to the present invention the metallic substrate is a flaky metallic substrate. In a further embodiment, the flaky metallic substrate has an average thickness (h50 value) in the range of 10 to 500 nm, more preferably in a range of 20 to 300 nm and most preferably in a range of 30 to 100 nm.

In general, the thickness of the metal or metallic particles can be determined with the aid of a scanning electron microscope (SEM). For this purpose, the particles are incorporated in a concentration of about 10 wt.-% into a two-component clearcoat, Autoclear Plus HS from Sikkens GmbH, with a sleeved brush, applied to a film with the aid of a spiral applicator (wet film thickness 26 μm) and dried. After a drying time of 24 h, transverse sections of these applicator drawdowns were produced. The transverse sections were analyzed by SEM (Zeiss supra 35) using the SE (secondary electrons) detector. For a valuable analysis of platelet particles, these should be well oriented plane-parallel to the substrate to minimize the systematic error of the angle of inclination caused by misaligned flakes.

Here, a sufficient number of particles should be measured so as to provide a representative mean value. Customarily, approximately 100 particles are measured. The h50 value is the median value of the particle thickness distribution measured using this method. This h50-value can be used as a measure of the mean thickness.

In one of the embodiments of the process according to the present invention the flaky metallic substrate has an aspect ratio in the range from 1500:1 to 10:1, preferably 1000:1 to 50:1 and more preferably 800:1 to 100:1 wherein the aspect ratio is defined as the ratio between the average pigment diameter (D50 value) and the average pigment thickness (h50 value).

The pigment size is typically indicated using D values which denote to quantile values of the volume averaged particle size distribution in frequency representation. Here, the number indicates the percentage of particles smaller than a specified size contained in a volume-averaged particle size distribution. For example, the D50 value indicates the size that is larger than 50% of the particles. These measurements are conducted e.g. by means of laser granulometry using a particle size analyser manufactured by Sympatec GmbH (model: Helos/BR). The measurement is conducted according to data from the manufacturer.

In one of the embodiments of the process according to the present invention the flaky metallic substrate is selected from aluminium, copper, zinc, gold-bronze, chromium, titanium, zirconium, tin, iron and steel flaky substrates or pigments of alloys of these metals. In a preferred embodiment the flaky metal substrate is aluminium, gold-bronze or copper and in a most preferred embodiment the flaky metal substrate is aluminium.

Despite the coating comprising a metal oxide the metallic substrate may also contain up to 30 wt. % of an oxide of the same metal. So, an aluminium substrate may contain up to 30 wt. % of aluminium oxide.

The metallic substrate may be manufactured by milling processes or by PVD processes (Physical Vapor Deposition). More preferred are flaky metallic substrate made by a PVD process and most preferably such flaky metallic substrate is an aluminium pigment.

In one of the embodiments of the process according to the present invention the metal oxide of the coating layer is selected from the group consisting of silicon oxide, aluminium oxide, boron oxide, zirconium oxide, cerium oxide, iron oxide, titanium oxide, chromium oxide, tin oxide, zinc oxide, molybdenum oxide, vanadium oxide, and mixtures thereof. Such oxides stabilise the surface of the metallic substrate against corrosion processes and contribute to a higher gloss level of the substrate treated by the method of the present invention and in addition this gloss level is more stable over time.

More preferred metal oxides of the coating layer are silicon oxide, molybdenum oxide, aluminium oxide and mixtures thereof. Most preferred is silicon oxide or molybdenum oxide. In another embodiment the coating layer is of molybdenum oxide and thereon a further metal oxide comprising silicon oxide is coated. Within this invention the term “metal oxide” is used to include for a specific metal any of its metal oxides, any of its metal hydroxides, any of its metal oxide hydrates and mixtures thereof.

According to this invention the metal oxide of the coating layer is based on a different metal as the metallic substrate itself. Some metallic substrates form natural oxides under ambient conditions. These natural metal oxides, however, do not provide sufficient corrosion stability or mechanical stiffness to the metallic substrate.

The most prominent example is aluminium which forms an aluminium oxide/hydroxide coating of a few nanometre thickness when coming into contact with oxygen and/or humidity.

For the avoidance of doubt, such layer of natural oxides formed on a metallic substrate under ambient condition, is not considered to be a surface treatment of the metallic substrate in accordance with the present invention.

In one embodiment, the substrate is an aluminium substrate coated with silicon oxide or molybdenum oxide as first coating layer and silicon oxide as second coating layer.

In further embodiments the coating layer contains the metal oxide, preferably silicon oxide, more preferably silicon dioxide, in an amount of at least 60 wt.-%, further preferably at least 70 wt.-%, further preferably at least 80 wt.-%, further preferably at least 95 wt.-%, each based on the total weight of the metal oxide or silicon oxide containing coating.

In other embodiments the remaining compounds up to 100 wt.-% in the metal oxide coating layer, comprise or consist of a further metal oxide different from silicon oxide leading to a mixed metal oxide layer surrounding the flaky metal substrate.

In another embodiments, the remaining compounds up to 100 wt.-% in the metal oxide coating layer, comprise or consist of organic material thus forming a hybrid metal oxide/organic coating layer.

In certain embodiments this organic material comprises or consists of organic oligomers and/or polymers. That is to say, the metal oxide coating, can be formed as a hybrid layer of metal oxide coating and organic oligomers and/or organic polymers, which preferably penetrate each other. Such kind of hybrid coatings can be made by simultaneous formation of metal oxide coating, (preferably by a sol-gel synthesis) and the formation of a polymer or oligomer. Thus, the hybrid layer is preferably an essentially homogeneous layer in which the metal oxide coating, and organic oligomer(s) and/or organic polymer(s) are essentially uniformly distributed within the coating. Metal effect pigments coated with such hybrid layers are disclosed in EP 1812519 B1 or in WO 2016/120015 A1. Such hybrid layers enhance the mechanical properties of the coating layer.

According to another embodiment of the invention, the metal oxide hybrid coating layer contains 70 to 95 wt.-%, preferably 80 to 90 wt.-%, silicon oxide, preferably silicon dioxide, and 5 to 30 wt.-%, preferably 10 to 20 wt.-% of organic oligomer and/or organic polymer, each based on the total weight of the metal oxide coating layer.

Organofunctional silane(s) are preferred for use as organic network formers in such hybrid coating layer. The organofunctional silane(s) can bind to the silicon oxide network following the hydrolysis of a hydrolysable group. By way of hydrolysis, the hydrolysable group is usually substituted by an OH group, which then forms a covalent bond with OH groups in the inorganic silica network with condensation.

The hydrolysable group is preferably halogen, hydroxyl, or alkoxy having from 1 to 10 carbon atoms preferably 1 to 2 carbon atoms, which may be linear or branched in the carbon chain, and mixtures thereof.

Suitable organofunctional silanes are, for example, many representatives produced by Evonik and products sold under the trade name “Dynasylan”. For example, 3-methacryloxypropyl trimethoxysilane (Dynasylan MEMO) can be used to form a (meth)acrylate or polyester, vinyl tri(m)ethoxysilane (Dynasylan VTMO or VTEO) to form a vinyl polymer, 3-mercaptopropyl tri(m)ethoxysilane (Dynasylan MTMO or 3201) for copolymerization in rubber polymers, aminopropyl trimethoxysilane (Dynasylan AMMO) or N2-aminoethyl-3-aminopropyl trimethoxysilane (Dynasylan DAMO) to form a β-hydroxylamine or 3-glycidoxypropyl trimethoxysilane (Dynasylan GLYMO) to form a urethane network or polyether network.

Other examples of silanes with vinyl or (meth)acrylate functionalities are: isocyanato triethoxy silane, 3-isocyanatopropoxyl triethoxy silane, vinyl ethyl dichlorosilane, vinyl methyl dichlorosilane, vinyl methyl diacetoxy silane, vinyl methyl diethoxy silane, vinyl triacetoxy silane, vinyl trichlorosilane, phenyl vinyl diethoxy silane, phenyl allyl diethoxy silane, phenyl allyl dichlorosilane, 3-methacryloxypropyl triethoxy silane, methacryloxy propyl trimethoxy silane, 3-acryloxypropyl trimethoxy silane, 2-methacryloxyethyl tri-(m)ethoxy silane, 2-acryloxyethyl tri(m)ethoxy silane, 3-methacryloxypropyl tris(methoxy-ethoxy)silane, 3-methacryloxypropyl tris(butoxyethoxy)silane, 3-methacryloxypropyl tris(propoxy)silane or 3-methacryloxypropyl tris(butoxy)silane.

In a preferred development of the invention, both silicon oxide, preferably silicon dioxide, and an organic network of oligomers and/or polymers are present as an interpenetrating network.

For the purposes of the present invention, “organic oligomers” in the hybrid layer are taken to mean the term usually employed in polymer chemistry: i.e. the linkage of from two to twenty monomer units (Hans-Georg Elias, “Makromoleküle” 4^{th} Edition 1981, Huethig & Wepf Verlag Basel). Polymers are linkages of more than twenty monomer units.

The average chain length of the organic segments can be varied by varying the ratio of monomer concentration to the concentration of organic network formers. The average chain length of the organic segments is from 2 to 10.000 monomer units, preferably from 3 to 5.000 monomer units, more preferably from 4 to 500 monomer units and even more preferably from 5 to 30 monomer units. Furthermore, in other embodiments the organic polymers have an average chain length of from 21 to 15.000 monomer units, more preferably from 50 to 5.000 monomer units and most preferably from 100 to 1.000 monomer units, for use as the organic component.

In another embodiment of the invention the metal oxide containing coating layer consists in a mixed layer of a metal oxide coating, preferably silicon oxide, more preferably silicon dioxide and organofunctional silanes, which have functional groups which are not polymerized or oligomerized. Such kind of organofunctional silanes are called network modifiers.

Preferably, the network modifiers are organofunctional silanes with the formula

R_{z}SiX_{(4-z)}

In this formula, z is an integer from 1 to 3, R is an unsubstituted, unbranched or branched alkyl chain having 1 to 24 C atoms or an aryl group having 6 to 18 C atoms or an arylalkyl group having 7 to 25 C atoms or mixtures thereof, and X is a halogen group and/or preferably an alkoxy group. Preference is given to alkyl silanes having alkyl chains in a range of 1 to 18 C atoms or to aryl silanes having phenyl groups. R may also be joined cyclically to Si, in which case z is typically 2. X is most preferably ethoxy or methoxy.

Mixtures of organofunctional silanes with different z-values may also be employed. Preferred examples of such network modifying organofunctional silanes are alkyl or aryl silanes. Examples for these silanes are butyl trimethoxy silane, butyl triethoxy silane, octyl trimethoxy silane, octyl triethoxy silane, decyl trimethoxy silane, decyl trimethoxy silane, hexadecyl trimethoxy silane, hexadecyl triethoxy silane, phenyl trimethoxy silane, phenyl triethoxy silane, diphenyl dimethoxy silane, diphenyl diethoxy silane, and mixtures thereof.

In one of the embodiments of the process according to the present invention the metallic substrate comprises a second coating layer of a compound having at least two terminal functional groups which are the same or different from each other and which are spaced by a spacer. It was found that at least one functional group is bound to the metallic substrate having a first coating layer of a metal oxide. At least one other functional group is directed outwardly towards the treated surface of the substrate.

Surface modification of coated flaky metal substrates:

The surface of the flaky particles treated with a coating layer comprising a metal oxide and optionally a further coating layer, is then further modified by a surface modification which is at least one heteropoly siloxane or a compound having at least two terminal functional groups which are the same or different from each other and which are spaced by a spacer, wherein at least one terminal functional group is capable of being chemically bound to the coating layer comprising the metal oxide. In most preferred embodiments the surface modification is bound to the top surface of the metal oxide.

This surface modification enables to change and to control the surface of the metal oxide with respect to e.g. hydrophilic and hydrophobic surface properties. Thus an optimal balance can be found with respect to the respective affinities of the coated particles, especially coated flaky metal effect pigments to the donor and as well as to the substrate surfaces.

As terminal functional groups alkoxy silyl groups (for example methoxy and ethoxy silanes), halosilanes (for example chlorosilanes) or acid groups of phosphoric acid esters or phosphonic acids and phosphonic acid esters can be considered here. The described groups are linked by way of spacers of greater or lesser length to a second, lacquer-friendly group. The spacer involves unreactive alkyl chains, siloxanes, polyethers, thioethers or urethanes or combinations of those groupings of the general formula (C, Si)ₙ Hₘ(N,O,S)ₓ, with n=1-50, m=2-100 and x=0-50. The lacquer-friendly group preferably involves acrylates, methacrylates, vinyl compounds, amino or cyano groups, isocyanates, epoxy, carboxy or hydroxy groups.

In certain embodiments, especially upon baking or hardening of the metal particles adhered to the substrate, those groups may chemically react with the reactive layer located between the substrate and the flaky metal pigments in a cross-linking reaction in accordance with the known chemical reaction mechanisms.

The particles used in the method according to the present are produced by first coating the metal substrate with a metal oxide preferably by sol-gel synthesis. Here the flaky metal effect pigments are dispersed in a solvent which is preferably an alcoholic solvent such as ethanol or isopropanol. A precursor of the metal oxide such as e.g. tetra ethoxy silane and water is added and the sol-gel reaction is catalysed by the addition of a base or an acid. Also, a twofold catalysis can be conducted, e.g. by first adding an acid and then a base as described in WO 2011/095341 A1.

In certain embodiments the organic acid used as acidic catalyst is selected from formic acid, acetic acid, propionic acid, oxalic acid, malonic acid, maleic acid, succinic acid, anhydrides of the stated acids, and mixtures thereof. It is especially preferred to use formic acid, acetic acid or oxalic acid and also mixtures thereof. According to certain embodiments of the invention, the amine catalyst is selected from dimethylethanolamine (DMEA), monoethanol amine, diethanol amine, triethanol amine, ethylene diamine (EDA), tert-butyl amine, monomethyl amine, dimethyl amine, trimethyl amine, monoethyl amine, diethyl amine, triethyl amine, ammonia, pyridine, pyridine derivative, aniline, aniline derivative, choline, choline derivative, urea, urea derivative, hydrazine derivative, and mixtures thereof.

As basic aminic catalyst for the sol-gel reaction it is particularly preferred to use ethylene diamine, monoethyl amine, diethyl amine, monomethyl amine, dimethyl amine, trimethyl amine, triethyl amine, ammonia or mixtures thereof.

After coating the flaky metal affect pigments with a metal oxide the surface of the metal oxide is coated with the surface modification agent. This step can be done in the same pot where the metal oxide was formed or in a different step. For example, the initially coated flaky particles are agitated and heated the in an organic solvent, mixed with a solution of a base in water or another solvent, the surface-modifying agent is added, the reaction mixture is cooled after 15 minutes to 24 hours of reaction time, and the effect pigment is separated by suction removal. The filter cake obtained can be dried in a vacuum at about 60°−130° C. For some surface-modifying agents it is not necessary to heat the mixture, for these materials simple mixing can be sufficient.

Silane-based surface-modifying agents are described for example in DE 40 11 044 C2. Phosphoric acid-based surface-modifying agents can be obtained inter alia as Lubrizol® 2061 and from LUBRIZOL® 2063 (Langer & Co), for example.

The surface-modifying agent can also be produced directly on the coated particles by chemical reaction from suitable starting substances. In that case the coated particles are also agitated and heated in an organic solvent. Optionally, they are then mixed with the solution of a base, for example and organic amine, that can act as a kind of catalyst for the modification reaction. Basically the same catalysts can be used which were also employed for the formation of the metal oxide. After about 1-6 hours of reaction time the suspension is cooled and subjected to suction removal of the flaky effect pigment. The filter cake obtained in that way can be dried in a vacuum at 60°−130° C. The reaction can also be conducted in a solvent in which the coated particles are later formed as a paste and used. That renders a drying step redundant.

As specific examples of surface-modifying agents that can be mentioned are for instance cross-linkable organo-functional silanes which after the hydrolysis operation are anchored with their reactive Si—OH units on the oxidic surface of the effect pigments. The potentially cross-linkable organic groups can later react with reactive agents of the treated parts of the printing substrate. Examples of suitable cross-linkable organo-functional silanes are as follows:

Vinyl trimethoxy silane, aminopropyl triethoxy silane, N-ethylamino-N-propyl dimethoxy silane, isocyanatopropyl triethoxy silane, mercaptopropyl trimethoxy silane, vinyl triethoxy silane, vinyl ethyl dichlorosilane, vinyl methyl diacetoxy silane, vinyl methoyl dichlorosilane, vinyl methyl diethoxy silane, vinyl triacetoxy silane, vinyl trichlorosilane, phenyl vinyl diethoxy silane, phenyl allyl dichlorosilane, 3-isocyanatopropoxyl triethoxy silane, methacryloxy propenyl trimethoxy silane, 3-methacryloxy propyl trimethoxy silane, 2-glycidyloxypropyl trimethoxy silane, 1,2-epoxy-4-(Ethyl triethoxysilyl)-cyclohexane, 3-acryloxypropyl trimethoxy silane, 2-methacryloxyethyl trimethoxy silane, 2-acryloxyethyl trimethoxy silane, 3-methacryloxypropyl triethoxy silane, -acryloxypropyl trimethoxy silane, 2-methacryloxyethyl triethoxy silane, 2-acryloxyethyl tri-ethoxy silane, 3-methacryloxypropyl tris(methoxyethoxy) silane, 3-methacryloxypropyl trist butoxyethoxy silane, 3-methacryloxypropyl tris(propoxy)silane, 3-methacryloxypropyl tris(butoxy)silane, 3-acryloxypropyl tris(methoxyethoxy) silane, 3-acryloxypropyl tris (butoxyethoxy)silane, -acryloxypropyl tris(propoxy)silane, 3-acryloxypropyl tris(butoxy)silane. 3-methacryloxypropyl trimethoxy silane is particularly preferred.

These and other silanes are commercially available for example from ABCR GmbH & Co, D-76151 Karlsruhe, under the Tradename “Dynasylan” from Evonik, Essen, Germany or from Sivento Chemie GmbH, D-40468 Dusseldorf. Vinyl phosphonic acid or vinyl phosphonic acid diethyl ester can also be listed here as bonding agents (manufacturer Evonik, Essen, Germany).

It is also possible to modify the surface of the initially coated particle with a layer which includes side by side one or more of the above-mentioned hydrophobing alkyl silanes (for example described in EP 0 634 459 A2) and at least one other reactive species. Depending on the specific demands made on the pigment, the proportion of the surface-modifying agent described herein in that layer can basically be between 10% and 100%. It is particularly preferred however if the proportion of the reactive species, preferably a reactive silane species is 10, 30, 50, 75 or 100 wt-%, based on the total amount of surface modifying agents. Such different ratios of a reactive species to e.g. a hydrophobic alkyl silane provides for graduation of the operative bonding forces to the surface of either the donor substrate or the treated parts of the printing substrate.

In one of the embodiments of the process according to the present invention the metallic substrate or the coated metallic substrate comprises a surface modification of a heteropolysiloxane which is prepared from components comprising at least one aminosilane component and at least one alkylsilane component.

The heteropolysiloxane can be a precondensed heteropolysiloxane prepared by mixing aminoalkylalkoxysilanes with alkyltrialkoxysilanes and/or dialkyldialkoxysilanes, mixing this mixture with water, adjusting the pH of the reaction mixture to a value between 1 and 8, and removal of the alcohols present and/or produced in the reaction. These precondensed heteropolysiloxanes are essentially free of organic solvents. The aminoalkylalkoxysilanes, alkyltrialkoxysilanes, and dialkyldialkoxysilanes that can be used to prepare a precondensed heteropolysiloxane can be water-soluble or non-water soluble. Preferred heteropolysiloxanes can be obtained from Evonik Industries AG, 45128 Essen, Germany, under the brand names Dynasylan Hydrosil 2627, Dynasylan Hydrosil 2776, Dynasylan Hydrosil 2909, Dynasylan 1146, and Dynasylan Hydrosil 2907. Particularly preferred water-based heteropolysiloxanes are Dynasylan Hydrosil 2627, Dynasylan Hydrosil 2776, Dynasylan Hydrosil 2907, and Dynasylan Hydrosil 2909. According to a preferred variant of the invention, the precondensed heteropolysiloxane is selected from the group composed of Dynasylan Hydrosil 2627, Dynasylan Hydrosil 2776, Dynasylan Hydrosil 2909, Dynasylan 1146, Dynasylan Hydrosil 2907, and mixtures thereof.

The heteropolysiloxanes preferably have an average molecular weight of at least 500 g/mol, particularly preferably of at least 750 g/mol, and most particularly preferably of at least 1000 g/mol. The average molecular weight can be determined, for example, by means of NMR spectroscopic methods such as ²⁹Si-NMR, optionally in combination with ¹H-NMR. A description of such methods can be found, for example, in publications such as “Organofunctional alkoxysilanes in dilute aqueous solution: New accounts on the dynamic structural mutability, Journal of Organometallic 5 Chemistry, 625 (2001), 208-216.

The heteropolysiloxane can be applied in various ways. Addition of the polysiloxane, preferably in dissolved or dispersed form, to a suspension comprising the metal pigments to be coated has been found to be particularly advantageous. In order to provide the suspension comprising the metallic substrates to be coated, for example, a reaction product obtained from a prior coating step may be used together with a metal oxide, particularly silicon oxide.

In particular, the structure of the precondensed heteropolysiloxanes according to the invention can be chainlike, ladder-like, cyclic, crosslinked, or mixtures thereof. Moreover, it is preferred in further embodiments that the heteropolysiloxane be composed to at least 87 wt. % preferably at least 93 wt. %, and more preferably at least 97 wt. %, relative to the total weight of the heteropolysiloxanes, of silane monomer components selected from the group composed of aminosilanes, alkylsilanes, vinylsilanes, arylsilanes, and mixtures thereof. In particular, it is preferred that the heteropolysiloxane be composed of the aminosilane and alkylsilane components in the aforementioned amounts.

The silane monomers are used e.g. in the form of an alkoxide. This alkoxide is cleaved to initiate oligomerization or polymerization, and the silane monomers are converted or crosslinked to the respective heteropolysiloxane as a result of a condensation step. Preferably, methoxide and ethoxide are used as alkoxides in the present invention. Unless otherwise specified, the wt. % of the silane monomer components in the heteropolysiloxane within the meaning of the present invention is based on the weight of the silane monomers without the components that are cleaved by condensation into heteropolysiloxane, such as alkoxy groups. The production of such polysiloxanes is described in the literature. For example, corresponding manufacturing methods can be found in U.S. Pat. Nos. 5,808,125 A, 5,679,147 A and 5,629,400 A. Aminosilanes with 1 or 2 amino groups per Si have been found to be particularly advantageous for making up the heteropolysiloxanes according to the invention. In further embodiments, at least 92 wt. %, and preferably at least 97 wt. % of the aminosilane components contained in the heteropolysiloxane are selected from aminosilanes with 1 or 2 amino groups, in each case relative to the total weight of the aminosilane components contained in the heteropolysiloxane.

For example, (H₂N(CH₂)₃Si(OCH₃)₃, ((3-aminopropyl) (trimethoxy) silane, AMMO), (H₂N(CH₂)₃Si(OC₂H₅)₃ ((3-aminopropy/(triethoxy silane, AMEO), (H₂N(CH₂)₂NH (CH₂)₃Si(OCH₃)₃, ((N-2-aminoethy)-3-aminopropy) (trimethoxysilane), (DAMO)), (H₂N(CH₂)₂NH(CH₂)₃)Si(OC₂H₅)₃, ((N-(2-aminoethyl-3-aminopropyl)(triethoxy) silane), and mixtures thereof have been found to be advantageous. In further embodiments, the aminosilane components contained in the heteropolysiloxane are selected to at least 92 wt. %, and preferably at least 97 wt. %, from the aforementioned group, and mixtures thereof, in each case relative to the total weight of the aminosilane components contained in the heteropolysiloxane.

In further embodiments, it is preferred that the heteropolysiloxane used according to the invention contain only minor amounts of epoxysilanes, or none at all. Corresponding heteropolysiloxanes in conventional wet coating systems typically showed better adhesion. In particular, it is preferred in further embodiments for the heteropolysiloxane to comprise no more than 10 wt. %, preferably no more than 6 wt. %, more preferably no more than 4 wt. %, and even more preferably no more than trace amounts epoxysilane components relative in each case to the total weight of the heteropolysiloxane

It has also been found that only small amounts of heteropolysiloxane are typically sufficient. In further embodiments, the surface modification comprising at least one and preferably only one heteropolysiloxane has an average thickness of no more than 20 nm, and more preferably no more than 10 nm. In particular, it is preferred that the at least one and preferably only one heteropolysiloxane be present essentially in the form of a monolayer. It has been found to be particularly advantageous if at least one heteropolysiloxane is applied to a surrounding coating layer comprising silicon oxide. The application of coating layers composed essentially of at least one metal oxide is preferably conducted by means of the sol-gel process.

The heteropolysiloxanes used according to one aspect of the invention can be produced by condensation of e.g. alkylsilanes and aminosilanes. However, the person skilled in the art is aware that identical heteropolysiloxanes can also be produced by other means, for example by reaction of at least one alkylsilane, at least one halogenoalkylsilane, and at least one amine. Such heteropolysiloxanes, which could also formally be considered condensation products of corresponding alkylsilanes and aminosilanes, are included in the present invention. The person skilled in the art can select among various retrosynthetic routes based on awareness of the present invention and known expertise.

In further embodiments, it is also preferred for no more than 1 wt. % of the silane monomer components to be fluorinated silanes relative to the total weight of the heteropolysiloxane. Fluorinated silane components are preferably contained only in trace amounts in the applied heteropolysiloxane layer, or more preferably are absent from said layer.

The term “aminosilane” within the meaning of the present invention signifies that the relevant silane has at least one amino group. This amino group need not be directly bonded to the silicon atom of the silyl group. Examples of suitable aminosilanes can be found, for example, in U.S. Pat. No. 9,624,378 B2.

Examples of commercially available aluminium pigments that can be used in the process according to the present invention include Hydrolan®-type products, Hydroshine®-type products and Aquashine-type products (all ex ECKART GmbH) or Emeral® (all ex Toyo Aluminium, Japan) or Silbercote® (all ex Sillberline Manufacturing Co. Ltd.).

The donor surface:

The donor surface of the printing process in preferred embodiments is a hydrophobic surface, made typically of an elastomer that can be tailored to have properties as herein disclosed, generally prepared from a silicone-based material. Poly (dimethyl-siloxane) polymers, which are silicone-based, have been found suitable. In one embodiment, a fluid curable composition was formulated by combining three silicone-based polymers: a vinyl-terminated polydimethylsiloxane 5000 cSt (DMS V35, Gelest®, CAS No. 68083-19-2) in an amount of about 44.8% by weight of the total composition (wt. %), a vinyl functional polydimethyl siloxane containing both terminal and pendant vinyl groups (Polymer XP RV 5000, Evonik® Hanse, CAS No. 68083-18-1) in an amount of about 19.2 wt. %, and a branched structure vinyl functional polydimethyl siloxane (VQM Resin-146, Gelest®, CAS No. 68584-83-8) in an amount of about 25.6 wt. %. To the mixture of the vinyl functional polydimethyl siloxanes were added: a platinum catalyst, such as a platinum divinyltetramethyl disiloxane complex (SIP 6831.2, Gelest®, CAS No. 68478-92-2) in an amount of about 0.1 wt. %, an inhibitor to better control curing conditions, Inhibitor 600 of Evonik® Hanse, in an amount of about 2.6 wt. %, and finally a reactive cross-linker, such as a methyl-hydro siloxane-dimethyl siloxane copolymer (HMS 301, Gelest®, CAS No. 68037-59-2) in an amount of about 7.7 wt. %, which initiates the addition curing. This addition curable composition was shortly thereafter applied with a smooth leveling knife upon the support of the donor surface (e.g. an epoxy sleeve mountable on drum 10), such support being optionally treated (e.g. by corona or with a priming substance) to further the adherence of the donor surface material to its support. The applied fluid was cured for two hours at 100-120° C. in a ventilated oven so as to form a donor surface.

The hydrophobicity is to enable the particles exposed to selective stripping by the tacky film created on the receptive layer bearing substrate to transfer cleanly to the substrate without splitting.

The donor surface should be hydrophobic, that is to say the wetting angle with the aqueous carrier of the particles should exceed 90°. The wetting angle is the angle formed by the meniscus at the liquid/air/solid interface and if it exceeds 90°, the water tends to bead and does not wet, and therefore adhere, to the surface. The wetting angle or equilibrium contact angle Θ₀, which is comprised between and can be calculated from the receding (minimal) contact angle Θ, and the advancing (maximal) contact angle Θ_{A}, can be assessed at a given temperature and pressure of relevance to the operational conditions of the process. It is conventionally measured with a goniometer or a drop shape analyzer through a drop of liquid having a volume of 5 μl, where the liquid-vapor interface meets the solid polymeric surface, at ambient temperature (circa 23° C.) and pressure (circa 100 kPa). Contact angle measurements can for instance be performed with a Contact Angle analyzer—Krüss™; “Easy Drop” FM40Mk2 using distilled water as reference liquid.

This hydrophobicity may be an inherent property of the polymer forming the donor surface or may be enhanced by inclusion of hydrophobicity additives in the polymer composition. Additives that may promote the hydrophobicity of a polymeric composition may be, for example, oils (e.g., synthetic, natural, plant or mineral oils), waxes, plasticizers and silicone additives. Such hydrophobicity additives can be compatible with any polymeric material, as long as their respective chemical nature or amounts do not prevent proper formation of the donor surface, and for instance would not impair adequate curing of the polymeric material.

The roughness or finish of the donor surface will be replicated in the printed metallized surface. Therefore if a mirror finish or highly glossy appearance is required, the donor surface would need to be smoother than if a matte or satin look is desired. These visual effects can also be derived from the roughness of the printing substrate and/or of the receptive layer.

The donor surface can be the outer surface of a drum but this is not essential as it may alternatively be the surface of an endless transfer member having the form of a belt guided over guide rollers and maintained under an appropriate tension at least while it is passing through the coating apparatus. Additional architectures may allow the donor surface and the coating station to be in relative movement one with the other. For instance, the donor surface may form a movable plan which can repeatedly pass beneath a static coating station, or form a static plan, the coating station repeatedly moving from one edge of the plan to the other so as to entirely cover the donor surface with particles. Conceivably, both the donor surface and the coating station may be moving with respect to one another and with respect to a static point in space so as to reduce the time it may take to achieve entire coating of the donor surface with the particles dispensed by the coating station. All such forms of donor surfaces can be said to be movable (e.g. rotatably, cyclically, endlessly, repeatedly movable or the like) with respect to the coating station where any such passing donor surface can be coated with particles (or replenished with particles in exposed regions).

The donor surface may additionally address practical or particular considerations resulting from the specific architecture of the printing system. For instance, it can be flexible enough to be mounted on a drum, have sufficient abrasion resistance, be inert to the particles and/or fluids being employed, and/or be resistant to any operating condition of relevance (e.g. pressure, heat, tension, etc.). Fulfilling any such property tends to favorably increase the lifespan of the donor surface.

The donor surface, whether formed as a sleeve over a drum or a belt over guide rollers, may further comprise, on the side opposite the particle receiving outer layer, a body, which together with the donor surface may be referred to as a transfer member. The body may comprise different layers each providing to the overall transfer member one or more desired property selected, for instance, from mechanical resistivity, thermal conductivity, compressibility (e.g., to improve “macroscopic” contact between the donor surface and the impression cylinder), conformability (e.g. to improve “microscopic” contact between the donor surface and the printing substrate on the impression cylinder) and any such characteristic readily understood by persons skilled in the art of printing transfer members.

A further aspect of this invention is directed to the use of particles, wherein at least 50 wt. % of the particles are flaky metal pigments comprising a flaky metallic substrate and a surface treatment of the metallic substrate, wherein the surface treatment of the metallic substrate comprises at least one coating layer surrounding the metallic substrate comprising a metal oxide, and a surface modification layer of the coating layer comprising at least one heteropolysiloxane or a compound having at least two terminal functional groups which are the same or different from each other and which are spaced by a spacer, wherein at least one terminal functional group is capable of being chemically bound to the coating layer in a method of printing onto a surface of a substrate, which method comprises:
a. Providing a donor surface
b. Passing the donor surface through a coating station from which the donor surface exits coated with individual particles, and
c. Repeatedly performing the steps of
   i. Treating the surface of the substrate to render the affinity of the particles to at least selected regions of the surface of the substrate greater than the affinity of the particles to the donor surface,
   ii. Contacting the surface of the substrate with the donor surface to cause particles to transfer from the donor surface only to the treated selected regions of the surface of the substrate, thereby exposing regions of the donor surface from which particles are transferred to the corresponding regions on the substrate, and
   iii. Thereby generating a plurality of individual particles adhered to the treated surface of the substrate,
   iv. Returning the donor surface to the coating station to render the particle monolayer continuous in order to permit printing of a subsequent image on the surface of the substrate.

All embodiments mentioned above in the description in connection the inventive method of printing do equally apply to the use of particles in a method of printing onto a surface of a substrate as outline in the previous paragraph.

### EXAMPLES

TABLE 1
Starting materials:

| | |
|---|---|
| AF1 | A non-leafing aluminium pigment made by vacuum |
| | metallisation, dispersed in isopropanol, solid content |
| | 20 wt. %, average particle thickness 30-45 nm, particle |
| | size distribution (d10/d50/d90): 4 μm/7.9 μm/15.5 μm |
| AF2 | A non-leafing aluminium platin dollar pigment dispersed in |
| | isopropanol, solid content 44.3 wt. %, average particle |
| | thickness 25-40 nm, particle size distribution (d10/d50/d90): |
| | 4.3 μm/10.1 μm/18.4 μm |
| SD1 | A dispersion of diamino-/alkylfunctional oligomeric siloxane in |
| | water, solid content 25 wt. % |
| SD2 | A monomeric long-chain alkylfunctional silane |
| SD3 | Diamino-functional silane |
| SD4 | A dispersion of aminofunctional oligomeric siloxane in water, |
| | solid content 38 wt % |
| SD5 | Methacrylfunctional silane |
| TEOS | Tetraethylorthosilicate |

### Example 1

35,49 pbw of AF1 and 43,09 pbw of isopropanol were intimately mixed until a dispersion was obtained. 0,02 pbw of a peroxo molybdic acid solution (obtained by mixing 1 pbw of molybdic acid with 3 pbw of a 30% hydrogenperoxide solution) was added and the mixing was continued. Then, the dispersion was heated to 80° C. and 3,71 pbw of TEOS, 5,20 pbw of water, and 0,56 pbw of acetic acid were added. This mixture was stirred for some time while the temperature was kept at 80° C.

At time intervals, 0,28 pbw of ethylenediamine and 3,55 pbw of isopropanol were added while being stirred at 80° C. until in total 0,84 pbw of ethylenediamine was added. Then 0,35 pbw of SD2 and 0,09 pbw of SD3 were added while the mixture was stirred and kept at 80° C. The stirring at 80° C. was continued for a couple of hours. Thereafter the mixture was cooled, part of the solvent was removed and a paste of encapsulated aluminium particles was obtained.

### Example 2

13,23 pbw of AF2, 67,53 pbw of isopropanol, 4,31 pbw of water, and 0.07 pbw of Disperbyk 118 were intimately mixed until a dispersion was obtained. 5,03 pbw of TEOS was added and during mixing the dispersion was heated to 80° C. At time intervals, 0,13 pbw of ethylenediamine, 3,32 pbw of isopropanol, and 0,21 pbw of water were added while being stirred at 80° C. until in total 0,39 pbw of ethylenediamine was added. Then 0,25 pbw of SD4 and 0,25 pbw of SD5 were added while the mixture was stirred and kept at 80° C. The stirring at 80° C. was continued for some time. Thereafter the mixture was cooled, part of the solvent was removed and a paste of encapsulated aluminium particles was obtained.

### Example 3

The same as Example 1, but instead of silanes SD2 and SD3 0,50 pbw of SD1 were used as modification of the surface.

### Example 4

The pastes of aluminium particles obtained in each of the examples 1-3 was dispersed in water and applied to a substrate using the process described in WO2016/189515.

As a Comparative Example 1, a paste of aluminium flake (aluminium powder 6150 supplied by Quanzhou Manfong Metal Powder Co., China) was dispersed in water and applied to a substrate using the process described in WO 2016/189515.

As Comparative Example 2 a paste of aluminium flake coated with fatty acids AF2 (Silvershine S1100, Eckart GmbH) was used.

As Comparative Example 3 the aluminium paste of comparative example 2 was coated with SiO₂ according to the procedure of example 1. The silanes SD2 and SD3, however, were not added and thus the aluminium flake was coated only with SiO₂.

The gloss, gloss retention, and corrosion stability of the thus prepared samples were measured. With gloss retention it is meant to measure the gloss after the printing procedure has been cyclically conducted for a while. For example, the gloss after one day, two day and finally up to 30 days after printing was measured.

The samples prepared with the aluminium particles of examples 1-3 all showed a high initial gloss level, a good gloss retention and a good corrosion stability.

Especially the coated metal effect pigments according to Examples 1 and 3 exhibited an average gloss of about 800 gloss units measured at 20° using a Byk-micro TRI-gloss. The substrates printed with the comparative examples 1 and 2 showed a high initial gloss level, but the gloss retention was poor as this sample showed corrosion within two days after application.

In contrast to other inventive Examples and to Comparative Examples land 2 the effect pigment of Comparative Example 3 were not transferred in sufficient amount to the donor surface and hence the printing result to the substrate was not satisfactory.

1. A method of printing onto a surface of a substrate, the method comprising:
providing a donor surface,
passing the donor surface through a coating station from which the donor surface exits coated with individual particles, and
repeatedly performing a process comprising:
treating the surface of the substrate to render affinity of the particles to at least selected regions of the surface of the substrate greater than affinity of the particles to the donor surface,
contacting the surface of the substrate with the donor surface to cause particles to transfer from the donor surface only to the treated at least selected regions of the surface of the substrate, thereby generating a plurality of the individual particles adhered to the treated surface of the substrate, and exposing regions of the donor surface from which particles are transferred to corresponding regions on the substrate, and
returning the donor surface to the coating station to render the individual particles continuous in order to permit printing of a subsequent image on the surface of the substrate,
wherein at least 50 wt. % of the individual particles are metal pigments comprising a flaky metallic substrate and a surface treatment of the metallic substrate, wherein the surface treatment of the metallic substrate comprises at least one coating layer surrounding the metallic substrate comprising a metal oxide, and a surface modification of the coating layer comprising at least one heteropolysiloxane or a compound having at least two terminal functional groups which are the same or different from each other and which are spaced by a spacer, wherein at least one group of the at least two terminal functional groups is capable of being chemically bonded to the coating layer.

2. The method of claim 1, wherein the surface modification is bonded to the top surface of metal oxide.

3. The method of claim 1, wherein the donor surface exits the coating station coated with a monolayer of the individual particles.

4. The method of claim 1, wherein the flaky metallic substrate has an average thickness (h50 value) in the range of 10 to 500 nm.

5. The method of claim 1, wherein the flaky metallic substrate has an aspect ratio in the range from 1500:1 to 10:1, wherein the aspect ratio is defined as the ratio between the average pigment diameter (D50 value) and the average pigment thickness (h50 value).

6. The method of claim 1, wherein the flaky metallic substrate comprises one or more of aluminum, copper, zinc, gold-bronze, chromium, titanium, zirconium, tin, iron and steel flaky substrates or pigments of alloys of these metals.

7. The method of claim 1, wherein the flaky metallic substrate is made by a PVD process.

8. The method of claim 1, wherein a first coating layer of the at least one coating layer surrounding the metallic substrate comprises a metal oxide in an amount of at least 60 wt. %, based on the weight of the first coating layer.

9. The method of claim 8, wherein the metal oxide of the first coating layer comprises one or more of silicon oxide, aluminum oxide, boron oxide, zirconium oxide, cerium oxide, iron oxide, titanium oxide, chromium oxide, tin oxide, zinc oxide, molybdenum oxide, vanadium oxide, oxide hydrates thereof, and hydroxides thereof.

10. The method of claim 1, wherein the at least one heteropolysiloxane is prepared from components comprising at least one aminosilane component and at least one alkylsilane component.

11. The method of claim 1, wherein the surface modification of the coating layer comprises the compound having at least two terminal functional groups which are different from each other and which are spaced by a spacer.

12. The method of claim 1, wherein a receptive and/or adhesive layer is applied onto the substrate when treating the surface of the substrate.

13. The method of claim 1, wherein the donor surface is a hydrophobic surface.

14-15. (canceled)

16. The method of claim 1, wherein the flaky metallic substrate is an aluminum pigment made by a PVD process.

17. The method of claim 1, wherein the donor surface is a hydrophobic surface comprising an elastomer prepared from poly (dimethylsiloxane) polymers.
